(19) United States
(12) Patent Application Publication
(10) Pub. No.: US 2020/0365820 A1
(43) Pub. Date: Nov. 19, 2020

(54) ORGANIC EL ELEMENT, ORGANIC EL DISPLAY PANEL, AND MANUFACTURING METHOD OF ORGANIC EL ELEMENT

(71) Applicant: JOLED Inc., Tokyo (JP)

(72) Inventors: Yasuhiro SEKIMOTO, Tokyo (JP); Toshiyuki Akiyama, Tokyo (JP); Muneharu Sato, Tokyo (JP); Shinichiro Ishino, Tokyo (JP); Tomohiko Oda, Tokyo (JP); Mineki Hasegawa, Tokyo (JP)

(73) Assignee: JOLED Inc., Tokyo (JP)

(21) Appl. No.: 16/874,791

(22) Filed: May 15, 2020

(30) Foreign Application Priority Data
May 16, 2019 (JP) 2019-092916

(51) Int. Cl. H01L 51/50; H01L 51/56

(52) U.S. Cl. CPC H01L 51/5016; H01L 51/5092; H01L 51/5004; H01L 51/5206; H01L 51/5056; H01L 51/56; H01L 51/5072

(57) ABSTRACT

Provided is an organic electroluminescent element obtained by stacking an anode, a light emitting layer, an electron transport layer, and a cathode in that order, the organic electroluminescent element including an electron injection control layer in contact with both the light emitting layer and the electron transport layer, in which the light emitting layer contains a fluorescent material as a luminescent material, a lowest unoccupied molecular orbital level of a functional material contained in the electron injection control layer is higher than a lowest unoccupied molecular orbital level of a functional material contained in the electron transport layer by 0.1 eV or higher, and the lowest unoccupied molecular orbital level of the functional material contained in the electron injection control layer is equal to or higher than a lowest unoccupied molecular orbital level of a functional material contained in the light emitting layer.

### CROSS-REFERENCE TO RELATED APPLICATION

The present disclosure contains subject matter related to that disclosed in Japanese Priority Patent Application JP 2019-092916 filed in the Japan Patent Office on May 16, 2019, the entire content of which is hereby incorporated by reference.

### BACKGROUND

The present disclosure relates to improvement in the luminous efficiency and the lifetime in an organic electroluminescent (EL) element using a fluorescent material as a luminescent material.

In recent years, display devices using organic EL elements have been becoming popular.

The organic EL element has a structure in which at least a light emitting layer is sandwiched between an anode and a cathode. In the light emitting layer, the energy of excitons generated through recombination between electrons and electron holes (holes) is converted to light. In an organic semiconductor, two kinds of excitons (excited states), singlet excitons and triplet excitons, exist based on the spin state of the electron. In what is called a so-called fluorescent material, the energy of the singlet excitons is converted to light.

As related arts, in order to improve the luminous efficiency of the organic EL element, contrivances have been made, such as adjusting the balance between electrons and holes (for example, refer to Japanese Patent Laid-open No. 2008-187205) and using a phosphorescent material that emits light by triplet excitons (for example, refer to Japanese Patent Laid-open No. 2010-171368).

### SUMMARY

The present disclosure intends to extend the lifetime while keeping the luminous efficiency in an organic EL element using a fluorescent material.

An organic EL element according to an aspect of the present disclosure is an organic EL element obtained by stacking an anode, a light emitting layer, an electron transport layer, and a cathode in that order. The organic EL element includes an electron injection control layer in contact with both the light emitting layer and the electron transport layer. The light emitting layer contains a fluorescent material as a luminescent material. The lowest unoccupied molecular orbital (LUMO) level of a functional material contained in the electron injection control layer is higher than a LUMO level of a functional material contained in the electron transport layer by 0.1 eV or higher, and is equal to or higher than the LUMO level of a functional material contained in the light emitting layer.

In the present specification, that the LUMO level or the highest occupied molecular orbital (HOMO) level is high means that the difference between this level and the vacuum level of the electron is small, that is, the potential energy of the electron that exists at this level is high.

According to the organic EL element in accordance with the aspect of the present disclosure, the density of electrons that accumulate in the vicinity of the interface between the electron injection control layer and the light emitting layer lowers due to the electron injection barrier of injection from the electron transport layer to the electron injection control layer. Therefore, the deterioration of the fluorescent material due to the accumulating elements is inhibited and extension of the lifetime of the organic EL element can be expected.

### BRIEF DESCRIPTION OF THE DRAWINGS

FIG. 1 is a sectional view schematically depicting the configuration of an organic EL element 1 according to an embodiment;

FIG. 2 is a simple schematic diagram depicting a band diagram of a hole transport layer, a light emitting layer, an electron injection control layer, and an electron transport layer according to a working example;

FIGS. 3A to 3C are simple schematic diagrams depicting the relationship between the band diagram of the hole transport layer, the light emitting layer, the electron injection control layer, and the electron transport layer and the position of recombination between electrons and holes according to the working example and a comparative example;

FIGS. 4A to 4D are diagrams for explaining a luminescence region and depict the distribution in the light emitting layer regarding excitons generated in the light emitting layer;

FIGS. 5A to 5E are partial sectional views schematically depicting part of a manufacturing process of the organic EL element according to the embodiment.

FIG. 5A depicts the state in which a TFT layer has been formed on a base, FIG. 5B depicts the state in which an interlayer insulating layer has been formed on a substrate, FIG. 5C depicts the state in which a pixel electrode material layer has been formed on the interlayer insulating layer, FIG. 5D depicts the state in which pixel electrodes have been formed, and FIG. 5E depicts the state in which a partition wall material layer has been formed on the interlayer insulating layer and the pixel electrodes;

FIGS. 6A to 6C are partial sectional views schematically depicting part of the manufacturing process of the organic EL element according to the embodiment. FIG. 6A depicts the state in which partition walls have been formed, FIG. 6B depicts the state in which hole injection layers have been formed on the pixel electrodes, and FIG. 6C depicts the state in which the hole transport layers have been formed on the hole injection layers;

FIGS. 7A to 7C are partial sectional views schematically depicting part of the manufacturing process of the organic EL element according to the embodiment. FIG. 7A depicts the state in which the light emitting layers have been formed on the hole transport layers, FIG. 7B depicts the state in which the electron injection control layer has been formed on the light emitting layers and the partition walls, and FIG. 7C depicts the state in which the electron transport layer has been formed on the electron injection control layer;

FIGS. 8A to 8C are partial sectional views schematically depicting part of the manufacturing process of the organic EL element according to the embodiment. FIG. 8A depicts the state in which an electron injection layer has been formed on the electron transport layer, FIG. 8B depicts the state in which a counter electrode has been formed on the electron injection layer, and FIG. 8C depicts the state in which a sealing layer has been formed on the counter electrode;

FIG. 9 is a flowchart depicting the manufacturing process of the organic EL element according to the embodiment; and

FIG. 10 is a block diagram depicting the configuration of an organic EL display device including the organic EL element according to the embodiment.

### DETAILED DESCRIPTION OF THE PREFERRED EMBODIMENT

### Circumstances Leading to One Aspect of Present Disclosure

To use an organic EL element as a light emitting element, generation of excitons serving as the start state of luminescence is essential. Therefore, conventionally, the performance of hole injection from a hole transport layer to a light emitting layer and the performance of electron injection from an electron transport layer to the light emitting layer are enhanced and the carrier density in the light emitting layer is improved to enhance the probability of recombination between electrons and holes. Furthermore, as a configuration to further improve the carrier density in the light emitting layer, functional layers in which the HOMO level of the electron transport layer and/or the LUMO level of the hole transport layer is adjusted are selected so that hole leakage from the light emitting layer to the electron transport layer and electron leakage from the light emitting layer to the hole transport layer can be suppressed. This is because the carrier density in the light emitting layer can be improved and the probability of recombination between electrons and holes can be enhanced by such a configuration.

As excitons in an organic material, two kinds of excitons, singlet excitons and triplet excitons, exist based on the spin state of the electron. In the fluorescent material, the singlet excitons contribute to luminescence and the triplet excitons do not contribute to luminescence as described above. On the other hand, the ratio of the probability of generation of the singlet excitons to that of the triplet excitons is substantially 1 to 3. Therefore, improvement in the density of the singlet excitons is desired.

Studies have been made on using a triplet-triplet fusion (TTF) phenomenon by which plural triplet excitons are made to collide to generate the singlet excitons as improvement in the density of the singlet excitons in a fluorescent material with low luminous efficiency, particularly in a blue luminescent material with a short luminescence wavelength, or the like. To use this TTF, the density of the triplet excitons needs to be improved. That is, the exciton density needs to be improved by narrowing the recombination region of electrons and holes.

As one of methods for narrowing the recombination region of electrons and holes, there is a method in which the injection amount of either electrons or holes to the light emitting layer is set sufficiently larger than the injection amount of the other and thereby the recombination region is localized to the vicinity of an interface on either the hole transport layer side or the electron transport layer side in the light emitting layer.

However, in this method, the deterioration of the material used for the light emitting layer is promoted due to accumulation of carriers at high density in the vicinity of the interface between the light emitting layer and the adjacent layer. This results in shortening of the lifetime of the organic EL element.

Therefore, the inventors have made studies on a technique for improving the density of excitons without accumulating carriers at the interface between the light emitting layer and the adjacent layer, and have reached an aspect of the present disclosure.

### ASPECTS OF DISCLOSURE

An organic EL element according to an aspect of the present disclosure is an organic EL element obtained by stacking an anode, a light emitting layer, an electron transport layer, and a cathode in that order. The organic EL element includes an electron injection control layer in contact with both the light emitting layer and the electron transport layer. The light emitting layer contains a fluorescent material as a luminescent material. The lowest unoccupied molecular orbital (LUMO) level of a functional material contained in the electron injection control layer is higher than the LUMO level of a functional material contained in the electron transport layer by 0.1 eV or higher, and is equal to or higher than the LUMO level of a functional material contained in the light emitting layer.

A manufacturing method of an organic EL element according to an aspect of the present disclosure is a manufacturing method of an organic EL element including preparing a substrate, forming a pixel electrode over the substrate, forming a light emitting layer containing a fluorescent material as a luminescent material over the pixel electrode, forming an electron injection control layer on the light emitting layer, forming an electron transport layer on the electron injection control layer, and forming a cathode over the electron transport layer. The lowest unoccupied molecular orbital (LUMO) level of a functional material contained in the electron injection control layer is higher than the LUMO level of a functional material contained in the electron transport layer by 0.1 eV or higher, and is equal to or higher than the LUMO level of a functional material contained in the light emitting layer.

According to the organic EL element or the manufacturing method of an organic EL element in accordance with the aspect of the present disclosure, electrons are accumulated on the side of the electron injection control layer in the electron transport layer due to the electron injection barrier of injection from the electron transport layer to the electron injection control layer. On the other hand, an electron injection barrier does not exist between the electron injection control layer and the light emitting layer and therefore electrons injected into the electron injection control layer are easily injected into the light emitting layer. Accordingly, the density of electrons that accumulate in the vicinity of the interface between the electron injection control layer and the light emitting layer lowers. Therefore, the deterioration of the fluorescent material due to the accumulating electrons is inhibited and extension of the lifetime of the organic EL element can be expected.

In the organic EL element according to the aspect of the present disclosure, the LUMO level of the functional material contained in the electron injection control layer may be higher than the LUMO level of the functional material contained in the light emitting layer by 0.1 eV or higher.

Due to this, the performance of electron injection from the electron injection control layer to the light emitting layer is improved, which provides success in lowering of the drive voltage and improvement in the luminous efficiency.

In the organic EL element according to the aspect of the present disclosure, the highest occupied molecular orbital (HOMO) level of the functional material contained in the electron injection control layer may be lower than the HOMO level of the functional material contained in the light emitting layer.

Due to this, outflow of holes from the light emitting layer to the electron injection control layer can be inhibited and the hole density in the light emitting layer can be improved. Therefore, the exciton density in the light emitting layer can be further improved.

In the organic EL element according to the aspect of the present disclosure, the hole mobility of the light emitting layer may be higher than the electron mobility of the light emitting layer.

Due to this, the probability of recombination between hole and electron can be enhanced on the cathode side relative to the center of the light emitting layer, and the lifetime can be extended while higher luminous efficiency is obtained.

In the organic EL element according to the aspect of the present disclosure, the distance between the luminescence center of the light emitting layer and a surface of the light emitting layer on the side of the cathode may be shorter than the distance between the luminescence center of the light emitting layer and a surface of the light emitting layer on the side of the anode.

Due to this, the exciton density is improved on the cathode side relative to the center of the light emitting layer, and the lifetime can be extended while higher luminous efficiency is obtained.

In the organic EL element according to the aspect of the present disclosure, the energy of a singlet exciton in the functional material contained in the electron injection control layer may be higher than the energy of a singlet exciton in the functional material contained in the light emitting layer.

Due to this, lowering of the luminous efficiency through outflow of the energy of the singlet exciton in the functional material of the light emitting layer to the electron injection control layer can be inhibited. In addition, improvement in the luminous efficiency can be intended by using the energy of partial singlet excitons in the functional material of the electron injection control layer for luminescence.

In the organic EL element according to the aspect of the present disclosure, the energy of a triplet exciton in the functional material contained in the electron injection control layer may be higher than the energy of a triplet exciton in the functional material contained in the light emitting layer.

Due to this, lowering of the luminous efficiency through outflow of the energy of the triplet exciton in the functional material of the light emitting layer to the electron injection control layer can be inhibited. In addition, improvement in the luminous efficiency can be intended by using the energy of partial triplet excitons in the functional material of the electron injection control layer for luminescence through the TTF.

An organic EL display panel according to an aspect of the present disclosure may include a plurality of the organic EL elements according to the aspect of the present disclosure over a substrate.

### Embodiment

An organic EL element according to an embodiment will be described below. The following description is exemplification for explaining a configuration and operation and effects according to one aspect of the present disclosure and is not limited to the following modes except for the essential part of the present disclosure.

### 1. Configuration of Organic EL Element

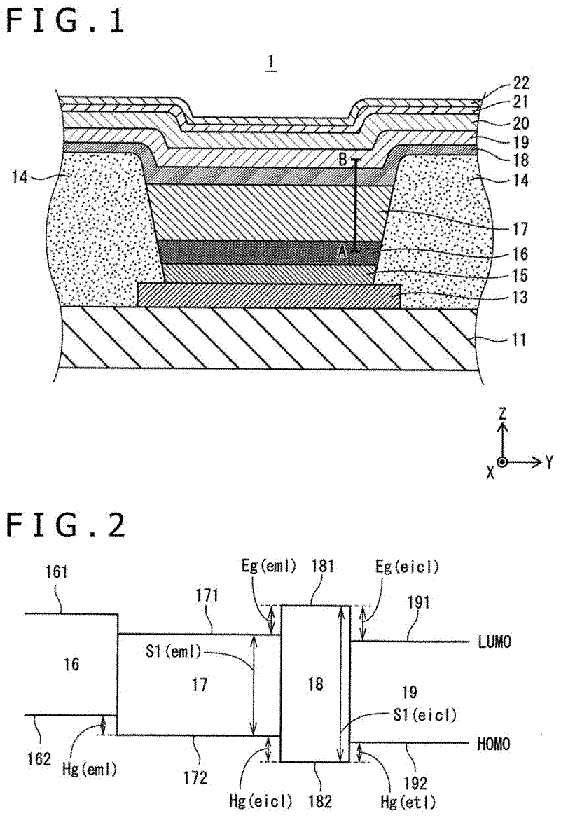

FIG. 1 is a diagram schematically depicting the sectional structure of an organic EL element 1 according to the present embodiment. The organic EL element 1 includes an anode 13, a hole injection layer 15, a hole transport layer 16, a light emitting layer 17, an electron injection control layer 18, an electron transport layer 19, an electron injection layer 20, and a cathode 21.

In the organic EL element 1, the anode 13 and the cathode 21 are disposed opposed to each other in such a manner that the main surfaces face each other, and the light emitting layer 17 is formed between the anode 13 and the cathode 21.

On the side of the anode 13 with respect to the light emitting layer 17, the hole transport layer 16 is formed in contact with the light emitting layer 17. The hole injection layer 15 is formed between the hole transport layer 16 and the anode 13.

On the side of the cathode 21 with respect to the light emitting layer 17, the electron injection control layer 18 is formed in contact with the light emitting layer 17. Between the electron injection control layer 18 and the cathode 21, the electron transport layer 19 and the electron injection layer 20 are formed in that order from the side of the electron injection control layer 18.

### [1.1 Respective Constituent Elements of Organic EL Element]

### <Anode>

The anode 13 includes at least one of a metal layer formed of a metal material and a metal oxide layer formed of a metal oxide. The film thickness of the anode 13 is set as small as approximately 1 to 50 nm and the anode 13 has light transmissivity. Although the metal material is a light reflective material, the light transmissivity can be ensured by setting the film thickness of the metal layer as small as 50 nm or smaller. Therefore, although part of light from the light emitting layer 17 is reflected by the anode 13, the remaining part is transmitted through the anode 13.

As the metal material to form the metal layer included in the anode 13, Ag, a silver alloy composed mainly of Ag and Al, and an Al alloy composed mainly of Al are cited. As the Ag alloy, magnesium-silver alloy (MgAg) and indium-silver alloy are cited. Ag is preferable in that it has low resistivity basically and the Ag alloy is preferable in that it is excellent in heat resistance and corrosion resistance and can keep favorable electrical conductivity for a long period. As the Al alloy, magnesium-aluminum alloy (MgAl) and lithium-aluminum alloy (LiAl) are cited. As other alloys, lithium-magnesium alloy and lithium-indium alloy are cited.

The metal layer included in the anode 13 may be formed of a single layer of an Ag layer or MgAg alloy layer, for example. Alternatively, a layer-stacking structure of Mg layer and Ag layer (Mg/Ag) or a layer-stacking structure of MgAg alloy layer and Ag layer (MgAg/Ag) may be employed.

As the metal oxide to form the metal oxide layer included in the anode 13, indium tin oxide (ITO) and indium zinc oxide (IZO) are cited.

Furthermore, the anode 13 may be formed of a metal layer alone or a metal oxide layer alone. However, a layer-stacking structure obtained by stacking a metal oxide layer on a metal layer or a layer-stacking structure obtained by stacking a metal layer on a metal oxide layer may be employed.

However, the anode 13 may have a configuration including a metal layer composed of a light reflective metal material depending on the material configuration of the cathode 21. As specific examples of the metal material having light reflectivity, silver (Ag), aluminum (Al), aluminum alloy, molybdenum (Mo), APC (alloy of silver, palladium, and copper), ARA (alloy of silver, rubidium, and gold), MoCr (alloy of molybdenum and chromium), MoW (alloy of molybdenum and tungsten), NiCr (alloy of nickel and chromium), and so forth are cited.

### <Hole Injection Layer>

The hole injection layer 15 has a function of promoting injection of holes from the anode 13 to the light emitting layer 17. The hole injection layer 15 is a coating film, for example, and is formed through applying and drying of a solution containing a hole injection material as a solute, for example. The hole injection layer 15 may be formed of an evaporated film. For example, the hole injection layer 15 is composed of an electrically-conductive polymer material such as PEDOT:PSS (mixture of polythiophene and polystyrene sulfonate), polyfluorene, derivative thereof, polyallylamine, or derivative thereof or an oxide of Ag, Mo, chromium (Cr), vanadium (V), tungsten (W), nickel (Ni), iridium (Ir), or the like.

### <Hole Transport Layer>

The hole transport layer 16 has a function of transporting holes injected from the hole injection layer 15 to the light emitting layer 17. The hole transport layer 16 is a coating film, for example, and is formed through applying and drying of a solution containing a hole transport material as a solute, for example. The hole transport layer 16 may be formed of an evaporated film. For example, it is possible to use a polymer compound such as polyfluorene, derivative thereof, polyallylamine, or derivative thereof, or the like.

### <Light Emitting Layer>

The light emitting layer 17 has a function of emitting light through recombination between holes and electrons. The position of recombination between hole and electron in the light emitting layer has distribution. Therefore, it is preferable that the film thickness of the light emitting layer be larger than the width of distribution of recombination. In one mode of the embodiment, the film thickness of the light emitting layer 17 is equal to or larger than 30 nm. Furthermore, in one mode of the embodiment, the film thickness of the light emitting layer 17 is equal to or larger than 40 nm. Furthermore, generally the mobility of the luminescent material is lower compared with the mobility of the charge transport material and designing a small film thickness of the light emitting layer contributes to reduction in the drive voltage of the element. Therefore, in one mode of the embodiment, the film thickness of the light emitting layer 17 is equal to or larger than 80 nm. Moreover, in one mode of the embodiment, the film thickness of the light emitting layer 17 is equal to or larger than 120 nm.

The light emitting layer 17 is a coating film, for example, and is formed through applying and drying of a solution containing a material to form the light emitting layer as a solute, for example. The light emitting layer 17 may be formed of an evaporated film.

As the material to form the light emitting layer 17, an organic material that is a publicly-known fluorescent substance can be used. For example, it is possible to use oxynoid compound, perylene compound, coumarin compound, azacoumarin compound, oxazole compound, oxadiazole compound, perinone compound, pyrrolopyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylenepyran compound, dicyanomethylenethiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, and so forth.

As described later, it is preferable that the hole mobility be higher than the electron mobility in the light emitting layer 17, and it is preferable to use a fluorescent material having such a characteristic or use an organic material having such a characteristic as a host material. As the host material in the case of using a fluorescent material as a dopant, an amine compound, fused polycyclic aromatic compound, or heterocyclic compound can be used, for example. As the amine compound, a monoamine derivative, diamine derivative, triamine derivative, or tetraamine derivative can be used, for example. As the fused polycyclic aromatic compound, an anthracene derivative, naphthalene derivative, naphthacene derivative, phenanthrene derivative, chrysene derivative, fluoranthene derivative, triphenylene derivative, pentacene derivative, or perylene derivative can be used, for example. As the heterocyclic compound, a carbazole derivative, furan derivative, pyridine derivative, pyrimidine derivative, triazine derivative, imidazole derivative, pyrazole derivative, triazole derivative, oxazole derivative, oxadiazole derivative, pyrrole derivative, indole derivative, azaindole derivative, azacarbazole derivative, pyrazoline derivative, pyrazolone derivative, or phthalocyanine derivative can be used, for example.

In the case of forming the light emitting layer from the fluorescent material and the host material, the concentration of the fluorescent material is equal to or higher than 1 wt % in one mode of the embodiment. Furthermore, in one mode of the embodiment, the concentration of the fluorescent material is equal to or higher than 10 wt %. Moreover, in one mode of the embodiment, the concentration of the fluorescent material is equal to or higher than 30 wt %.

### <Electron Injection Control Layer>

The electron injection control layer 18 has a function of limiting outflow of holes from the light emitting layer 17 to the electron injection control layer 18 and controlling injection of electrons from the electron transport layer 19 to the light emitting layer 17. The function of limiting outflow of holes from the light emitting layer 17 and controlling injection of electrons to the light emitting layer 17 is implemented based on design of the energy band structure to be described later. For stably implementing electron control by the electron injection control layer, design of the film thickness of the electron injection control layer by which the tunnel effect of carriers can be suppressed is preferable. In one mode of the embodiment, the film thickness of the electron injection control layer 18 is equal to or larger than 5 nm. Furthermore, in one mode of the embodiment, the film thickness of the electron injection control layer 18 is equal to or larger than 10 nm. Moreover, in terms of reduction in the element drive voltage, it is preferable that the film thickness of the electron injection control layer be small. In one mode of the embodiment, the film thickness of the electron injection control layer 18 is equal to or smaller than 50 nm. Furthermore, in one mode of the embodiment, the film thickness of the electron injection control layer 18 is equal to or smaller than 30 nm.

Furthermore, in the material of the electron injection control layer 18, it is preferable that the energy difference (band gap) between the LUMO level and the HOMO level, i.e. the energy of the singlet exciton, be larger than the energy difference between the LUMO level and the HOMO level (energy of the singlet exciton) in the material of the light emitting layer 17. Due to this configuration, when singlet excitons are generated in the material of the electron injection control layer 18, transition to singlet excitons of the fluorescent material of the light emitting layer 17 easily occurs. In addition, transition of singlet excitons of the fluorescent material of the light emitting layer 17 to singlet excitons of the material of the electron injection control layer 18 can be deterred. That is, part of the energy of the singlet excitons generated in the material of the electron injection control layer 18 can be utilized as the energy of the singlet excitons of the luminescent material. In addition, outflow of the energy of the singlet excitons of the luminescent material of the light emitting layer 17 to the electron injection control layer 18 can be deterred. This contributes to improvement in the luminous efficiency. Furthermore, similarly, it is preferable that the energy of the triplet exciton in the material of the electron injection control layer 18 be higher than the energy of the triplet exciton in the material of the light emitting layer 17. The electron injection control layer 18 is formed of an evaporated film, for example.

As the material of the electron injection control layer, π-electron low-molecular organic materials such as pyridine derivative, pyrimidine derivative, triazine derivative, imidazole derivative, oxadiazole derivative, triazole derivative, quinazoline derivative, and phenanthroline derivative are cited, for example.

### <Electron Transport Layer>

The electron transport layer 19 has a function of transporting electrons from the cathode 21 to the light emitting layer 17 through the electron injection control layer 18. The electron transport layer 19 is composed of an organic material having high electron transport performance. The electron transport layer 19 is formed of an evaporated film, for example. As the organic material used for the electron transport layer 19, π-electron low-molecular organic materials such as pyridine derivative, pyrimidine derivative, triazine derivative, imidazole derivative, oxadiazole derivative, triazole derivative, quinazoline derivative, and phenanthroline derivative are cited, for example.

### <Electron Injection Layer>

The electron injection layer 20 has a function of injecting electrons supplied from the cathode 21 to the side of the light emitting layer 17. The electron injection layer 20 is formed of an evaporated film, for example. The electron injection layer 20 is formed by doping an organic material having high electron transport performance with a doping metal selected from alkali metals, alkaline earth metals, lanthanides, or the like, for example. The doping metal is not limited to an elemental metal and may be used for doping as a compound such as a fluoride (for example, NaF) or quinolinium complex (for example, Alq₃, Liq). In the embodiment, Li used for doping as Liq. As the doping metal, lithium (Li), sodium (Na), potassium (K), rubidium (Rb), cesium (Cs), and francium (Fr) corresponding to alkali metals, calcium (Ca), strontium (Sr), barium (Ba), radium (Ra), and yttrium (Y) corresponding to alkaline earth metals, samarium (Sm), europium (Eu), and ytterbium (Yb) corresponding to lanthanides, and so forth are cited, for example.

As the organic material used for the electron injection layer 20, π-electron low-molecular organic materials such as oxadiazole derivative (OXD), triazole derivative (TAZ), and phenanthroline derivative (BCP, Bphen) are cited, for example.

### <Cathode>

The cathode 21 includes a metal layer composed of a light reflective metal material. As specific examples of the metal material having light reflectivity, silver (Ag), aluminum (Al), aluminum alloy, molybdenum (Mo), APC (alloy of silver, palladium, and copper), ARA (alloy of silver, rubidium, and gold), MoCr (alloy of molybdenum and chromium), MoW (alloy of molybdenum and tungsten), NiCr (alloy of nickel and chromium), and so forth are cited.

However, the cathode 21 may be formed of a light transmissive layer including at least one of a metal layer formed of a metal material and a metal oxide layer formed of a metal oxide depending on the material configuration of the anode 13. The film thickness of the metal layer in the cathode 21 is set as small as approximately 1 to 50 nm and the cathode 21 has light transmissivity. Although the metal material is a light reflective material, the light transmissivity can be ensured by setting the film thickness of the metal layer as small as 50 nm or smaller. Therefore, although part of light from the light emitting layer 17 is reflected by the cathode 21, the remaining part is transmitted through the cathode 21.

As the metal material to form the metal layer included in the cathode 21, Ag, a silver alloy composed mainly of Ag and Al, and an Al alloy composed mainly of Al are cited. As the Ag alloy, magnesium-silver alloy (MgAg) and indium-silver alloy are cited. Ag is preferable in that it has low resistivity basically and the Ag alloy is preferable in that it is excellent in heat resistance and corrosion resistance and can keep favorable electrical conductivity for a long period. As the Al alloy, magnesium-aluminum alloy (MgAl) and lithium-aluminum alloy (LiAl) are cited. As other alloys, lithium-magnesium alloy and lithium-indium alloy are cited.

The metal layer included in the cathode 21 may be formed of a single layer of an Ag layer or MgAg alloy layer, for example. Alternatively, a layer-stacking structure of Mg layer and Ag layer (Mg/Ag) or a layer-stacking structure of MgAg alloy layer and Ag layer (MgAg/Ag) may be employed.

As the metal oxide to form the metal oxide layer included in the cathode 21, indium tin oxide (ITO) and indium zinc oxide (IZO) are cited.

Furthermore, the cathode 21 may be formed of a metal layer alone or a metal oxide layer alone. However, a layer-stacking structure obtained by stacking a metal oxide layer on a metal layer or a layer-stacking structure obtained by stacking a metal layer on a metal oxide layer may be employed.

### <Others>

The organic EL element 1 is formed on a substrate 11. The substrate 11 is formed of a base 111 that is an insulating material. Alternatively, a wiring layer 112 may be formed on the base 111 that is an insulating material. As the base 111, a glass substrate, quartz substrate, silicon substrate, plastic substrate, or the like can be employed, for example. As the plastic material, either resin of thermoplastic resin and thermosetting resin may be used. For example, the following materials are cited and a layer-stacked body obtained by stacking one kind or two or more kinds among them can be used: polyethylene, polypropylene, polyamide, polyimide (PI), polycarbonate, acrylic resin, polyethylene terephthalate (PET), polybutylene terephthalate, polyacetal, other fluorine-based resins, various kinds of thermoplastic elastomers such as styrene-based, polyolefin-based, polyvinyl chloride-based, polyurethane-based, fluorine rubber-based, and chlorinated polyethylene-based elastomers, epoxy resin, unsaturated polyester, silicone resin, polyurethane, and so forth, or copolymers, blends, polymer alloys, and so forth composed mainly of them. As the material to configure the wiring layer 112, metal materials such as molybdenum sulfide, copper, zinc, aluminum, stainless steel, magnesium, iron, nickel, gold, and silver, inorganic semiconductor materials such as gallium nitride and gallium arsenide, organic semiconductor materials such as anthracene, rubrene, and poly (para-phenylene vinylene), and so forth are cited. A thin film transistor (TFT) layer formed by using them multiply may be employed.

Furthermore, an interlayer insulating layer 12 is formed on the substrate 11 although not depicted in the diagram. The interlayer insulating layer 12 is composed of a resin material and is a layer for planarizing steps in the upper surface of the TFT layer 112. As the resin material, a positive photosensitive material is cited, for example. Furthermore, as such a photosensitive material, acrylic resin, polyimide-based resin, siloxane-based resin, and phenolic resin are cited. Moreover, in the interlayer insulating layer 12, a contact hole is formed for each pixel.

When an organic EL display panel 100 is a bottom-emission type, the base 111 and the interlayer insulating layer 12 need to be formed of a light transmissive material. Moreover, if the TFT layer 112 exists, at least part of regions that exist below the pixel electrodes 13 in the TFT layer 112 needs to have light transmissivity.

Furthermore, a sealing layer 22 is formed on the organic EL element 1. The sealing layer 22 has a function of inhibiting organic layers such as the hole injection layer 15, the hole transport layer 16, the light emitting layer 17, the electron injection control layer 18, the electron transport layer 19, and the electron injection layer 20 from being exposed to water and being exposed to air, and is formed by using a translucent material such as silicon nitride (SiN) or silicon oxynitride (SiON), for example. Moreover, a sealing resin layer composed of a resin material such as an acrylic resin or silicone resin may be disposed on a layer formed by using a material such as silicon nitride (SiN) or silicon oxynitride (SiON).

When the organic EL display panel 100 is a top-emission type, the sealing layer 22 needs to be formed of a light transmissive material.

Although not depicted in FIG. 1, a color filter and an upper substrate may be stuck over the sealing layer 22 with the intermediary of the sealing resin. By sticking the upper substrate, the hole injection layer 15, the hole transport layer 16, the light emitting layer 17, the electron injection control layer 18, the electron transport layer 19, and the electron injection layer 20 can be protected from water, air, and so forth.

### 2. Energy Band Structure

The organic EL element 1 has a characteristic in the energy band structure of the light emitting layer 17, the electron injection control layer 18, and the electron transport layer 19. For simplification of explanation, a description of “energy level of the layer” is made. This is an abbreviation for the energy level of the organic material forming this layer. Regarding a layer composed of plural kinds of materials, the energy level of the representative organic material responsible for transporting electrons and/or holes is represented as the “energy level of the layer.”

FIG. 2 is a band diagram depicting the energy band structure of the organic EL element 1. In FIG. 2, the energy level of the LUMO (hereinafter, represented as “LUMO level”) and the energy level of the highest occupied molecular orbital (HOMO) (hereinafter, represented as “HOMO level”) regarding the hole transport layer 16, the light emitting layer 17, the electron injection control layer 18, and the electron transport layer 19 are depicted and representation is omitted regarding the other layers. Although the vacuum level of the electron is not depicted in FIG. 2, each of the LUMO level and the HOMO level has a larger difference from the vacuum level of the electron and has a lower energy level when existing closer to the lower side of the band diagram.

### [2.1 Electron Injection Barrier]

An energy barrier for injection of electrons from the side of the cathode 21 to the light emitting layer 17 exists at the interface of each layer from the cathode 21 to the light emitting layer 17. This energy barrier is attributed to the difference in the LUMO level between the layer on the side of the anode 13 relative to the interface and the layer on the side of the cathode 21. Hereinafter, the energy barrier for injection of electrons from the side of the cathode 21 to the side of the anode 13 at the interface between two layers adjacent to each other will be referred to as the “electron injection barrier.”

An electron injection barrier Eg(eicl) of injection from the electron transport layer 19 to the electron injection control layer 18 is defined by the difference between a LUMO level 181 of the organic material of the electron injection control layer 18 and a LUMO level 191 of the organic material of the electron transport layer 19. It is preferable for Eg(eicl) to satisfy the following expression (1). Furthermore, it is more preferable for Eg(eicl) to satisfy the following expression (2). In the present embodiment, the electron injection barrier Eg(eicl) is 0.22 eV.

Eg(eicl)≥0.1 eV expression (1)

Eg(eicl)≥0.2 eV expression (2)

An electron injection barrier Eg(eml) of injection from the electron injection control layer 18 to the light emitting layer 17 is defined by the difference between a LUMO level 171 of the organic material of the light emitting layer 17 and the LUMO level 181 of the organic material of the electron injection control layer 18. It is preferable that the LUMO level 171 of the organic material of the light emitting layer 17 have a lower energy level compared with the LUMO level 181 of the organic material of the electron injection control layer 18 and Eg(eml) satisfy the following expression (3). Furthermore, it is more preferable for Eg(eml) to satisfy the following expression (4). In the present embodiment, the electron injection barrier Eg(eml) is −0.15 eV.

Eg(eml)≤0 expression (3)

Eg(eml)≤−0.1 eV expression (4)

### [2.2 Hole Injection Barrier]

Meanwhile, an energy barrier for injection of holes from the side of the anode 13 to the side of the cathode 21 through the light emitting layer 17 exists at the interface of each layer from the anode 13 to the electron injection control layer 18. This energy barrier is attributed to the difference in the HOMO level between the layer on the side of the cathode 21 relative to the interface and the layer on the side of the anode 13. Hereinafter, the energy barrier for injection of holes from the side of the anode 13 to the side of the cathode 21 at the interface between two layers adjacent to each other will be referred to as the “hole injection barrier.”

A hole injection barrier Hg(eml) of injection from the hole transport layer 16 to the light emitting layer 17 is defined by the difference between a HOMO level 172 of the organic material of the light emitting layer 17 and a HOMO level 162 of the organic material of the hole transport layer 16. In the present embodiment, the hole injection barrier Hg(eml) is 0.11 eV.

A hole injection barrier Hg(eicl) of injection from the light emitting layer 17 to the electron injection control layer 18 is defined by the difference between a HOMO level 182 of the organic material of the electron injection control layer 18 and the HOMO level 172 of the organic material of the light emitting layer 17. It is preferable for Hg(eicl) to satisfy the following expression (5). Furthermore, it is more preferable for Hg(eicl) to satisfy the following expression (6). In the present embodiment, the hole injection barrier Hg(eicl) is 0.31 eV.

Hg(eicl)>0 expression (5)

Hg(eicl)≥0.3 eV expression (6)

### 3. Effects Brought by Configuration

[3.1 Effects Predicted from Band Diagram]

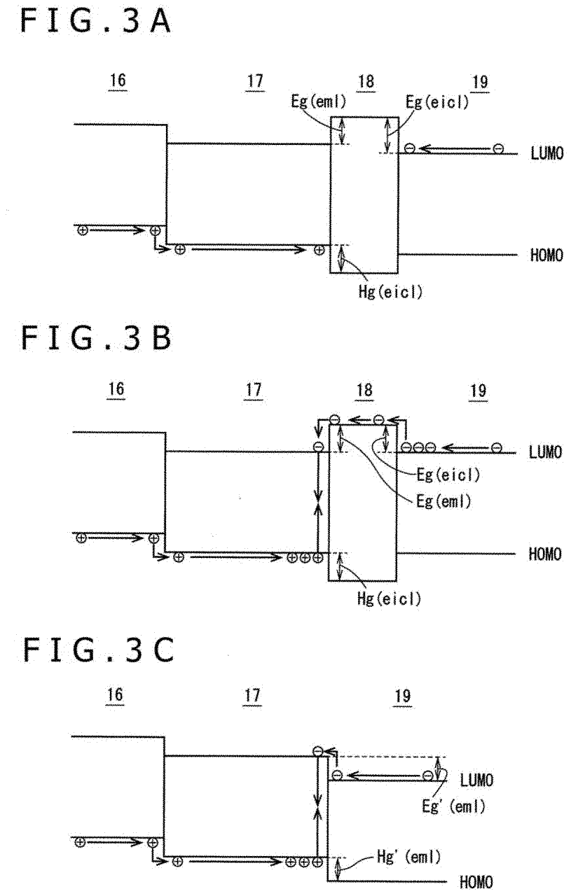

FIGS. 3A, 3B, and FIG. 3C are simple schematic diagrams that relate to a working example and a comparative example, respectively, and depict the band diagram of the hole transport layer 16, the light emitting layer 17, the electron injection control layer 18, and the electron transport layer 19 and recombination between electrons and holes.

FIG. 3C corresponds to an organic EL element that does not include the electron injection control layer 18. That is, the light emitting layer 17 and the electron transport layer 19 are adjacent. In this case, electrons injected from the cathode side accumulate at the interface between the light emitting layer 17 and the adjacent electron transport layer 19 due to an electron injection barrier Eg′(eml). Furthermore, electrons that have flown into the light emitting layer 17 recombine with holes in the vicinity of the interface with the electron transport layer in the light emitting layer and are consumed. Therefore, the luminescent material in the vicinity of the interface between the light emitting layer responsible for luminescence and the electron transport layer are exposed to the accumulating electrons at the interface, so that material deterioration is promoted.

In contrast, the following behavior is found in the organic EL element according to the embodiment. As depicted in the schematic diagram of FIG. 3A, electrons injected from the cathode side accumulate at the interface between the electron injection control layer 18 and the electron transport layer 19 due to the electron injection barrier Eg(eicl) in the organic EL element according to the embodiment. When a sufficient electric field is applied, as depicted in FIG. 3B, electrons go beyond the electron injection barrier Eg(eicl) and are injected into the light emitting layer 17, and the electrons that have flown into the light emitting layer 17 recombine with holes in the vicinity of the interface with the electron transport layer in the light emitting layer and are consumed. In this case, when comparison with the above-described comparison example of FIG. 3C is made, although the working example is the same in that the recombination region exists in the vicinity of the interface on the cathode side in the light emitting layer, the accumulation position of the injected electrons is the interface between the electron injection control layer and the electron transport layer, which is not adjacent to the light emitting layer. This provides the operation state in which material deterioration of the luminescent material in the vicinity of the interface on the cathode side in the light emitting layer responsible for luminescence is promoted less readily. Therefore, in the present working example, extension of the lifetime is expected with respect to the comparative example.

Furthermore, it is preferable that the energy (band gap) of singlet excitons of the material of the electron injection control layer 18 be higher than the energy (band gap) of singlet excitons of the fluorescent material of the light emitting layer 17. Because the energy of the singlet exciton of the material of the electron injection control layer 18 is higher than the energy of the singlet exciton of the fluorescent material, (a) when holes are injected into the electron injection control layer 18 and recombination occurs in the electron injection control layer 18 and singlet excitons are generated, it can be expected that the fluorescent material is excited and transition to the singlet excitons of the fluorescent material is caused, and (b) the singlet excitons of the fluorescent material can be inhibited from exciting the material of the electron injection control layer 18. Similarly, it is preferable that the energy of the triplet exciton of the material of the electron injection control layer 18 be higher than the energy of the triplet exciton of the fluorescent material of the light emitting layer 17. Due to this, (a) when triplet excitons are generated in the electron injection control layer 18, it can be expected that the fluorescent material is excited and transition to the triplet excitons of the fluorescent material is caused, and (b) the triplet excitons of the fluorescent material can be inhibited from exciting the material of the electron injection control layer 18.

It is preferable that the hole mobility be higher than the electron mobility in the light emitting layer 17. Due to the high hole mobility, holes come to readily concentrate in the vicinity of the interface with the electron injection control layer 18 in the light emitting layer 17 and the density of holes in the vicinity of the interface with the electron injection control layer 18 in the light emitting layer 17 can be improved. Furthermore, because the hole mobility is higher than the electron mobility, electrons that do not recombine are inhibited from moving to the side of the hole transport layer 16 and the occurrence place of recombination between electrons and holes concentrates near the interface with the electron injection control layer 18 in the light emitting layer 17. Therefore, the exciton density can be further improved. According to the present configuration, excitons concentrate near the interface with the electron injection control layer 18 in the light emitting layer 17 and thus the luminescence center also exists on the side of the electron injection control layer 18 relative to the center of the light emitting layer 17. Details relating to the luminescence center will be described later.

### [3.2 Characteristics of Element]

In order to evaluate the influence of the electron injection control layer 18 on characteristics of the organic EL element, the following samples were fabricated and the injection start voltage, the external quantum efficiency, and the lifetime of each sample were measured.

In an organic EL element according to a working example, H-1 (LUMO level: 3.0 eV, HOMO level: 5.9 eV) was used as the host material of the light emitting layer 17 and ET-1 (LUMO level: 2.9 eV, HOMO level: 6.2 eV) was used as the material of the electron injection control layer 18 and ET-2 (LUMO level: 3.0 eV, HOMO level: 6.4 eV) was used as the material of the electron transport layer 19. For both the LUMO level and the HOMO level, the vacuum level was deemed as 0. In the energy band structure according to the working example, Eg(eicl) was 0.1 eV and Eg(eml) was −0.1 eV and Hg(eicl) was 0.3 eV. The value of the HOMO level was measured by using a photoelectron spectroscope (AC-3 made by RIKEN KEIKI Co., Ltd.). Furthermore, the value of the LUMO level was obtained by deeming the optical absorption edge of a thin film as the energy gap and subtracting it from the value of the HOMO level.

In sample A that is the working example, the configuration according to the above-described embodiment was employed. On the other hand, in sample B that is a comparative example, a configuration was employed in which the electron injection control layer 18 was not disposed and the electron transport layer 19 was in contact with the light emitting layer 17 on the side of the cathode 21. Furthermore, as sample C that is a working example, an element in which the hole injection layer 15 and the hole transport layer 16 were not disposed and carriers in the light emitting layer 17 are only electrons (electron only device (EOD)) was employed. Furthermore, as sample D that is a comparative example, an EOD in which the hole injection layer 15, the hole transport layer 16, and the electron injection control layer 18 were not disposed and that corresponded to sample B was employed.

In Table 1, element characteristics of the above-described four kinds of samples are depicted. In this table, the characteristics of samples A and C as the working examples are depicted as relative values with respect to the characteristics of samples B and D as the comparative examples. According to comparison of the current injection start voltage of the EOD, the voltage in sample C was increased by 0.4 V compared with sample D.

On the other hand, according to comparison of the current injection start voltage of the light emitting element, no voltage difference was found between sample B, which did not have the electron injection control layer, and sample A having this layer.

TABLE 1

| | | Light emitting element | | |
|---|---|---|---|---|
| | EOD | | External | Lifetime |
| | Current | Current | quantum | (LT95) |
| | injection | injection | efficiency | Initial |
| | start | start | Luminance: | luminance: |
| | voltage | voltage | 1000 cd/m² | 1000 cd/m² |
| [Working | Sample C | Sample A | | |
| examples] | +0.4 V | ±0.0 V | 1.0 | 15.9 |
| Structure having | | | | |
| electron injection | | | | |
| control layer | | | | |
| [Comparative | Sample D | Sample B | | |
| examples] | (Reference | (Reference | 1.0 | 1.0 |
| Structure that | voltage) | voltage) | | |
| does not have | | | | |
| electron injection | | | | |
| control layer | | | | |

The above-described phenomenon will be considered as follows. In sample C, the injection performance of electrons to the light emitting layer 17 lowers compared with sample D due to the existence of the electron injection control layer 18. That is, the electron injection control layer 18 functions as an electron injection barrier. However, in sample A, the injection performance of electrons to the light emitting layer 17 does not lower compared with sample B although the electron injection control layer 18 exists. The difference between sample C and sample A is the existence of holes in the light emitting layer 17. Specifically, sample C is an electron only device (EOD) and holes are not injected into the light emitting layer 17 and recombination in the light emitting layer does not occur. In contrast, sample A is a bipolar device and hole injection into the light emitting layer 17 is made and recombination in the light emitting layer occurs. At this time, electrons injected into the light emitting layer are consumed due to the recombination and thereby the state in which the electron density in the light emitting layer is low is made, which promotes electron injection from the electron injection control layer side. For this reason, in sample A, the lowering of the injection performance of electrons to the light emitting layer 17 will occur less readily although the electron injection control layer 18 functions as an electron injection barrier.

As above, in sample A, the electron injection performance does not lower although the electron injection control layer is inserted. Therefore, the luminous efficiency is not affected as depicted in the item of the external quantum efficiency in Table 1.

Moreover, when a reference to the item of the lifetime in this table is made, it turns out that the lifetime is remarkably improved. The reason for this will be because, as described above, the accumulation position of electrons injected from the cathode side is not adjacent to the light emitting layer due to the insertion of the electron injection control layer and therefore the deterioration of the luminescent material due to the electrons occurs less readily.

### [3.3 Luminescence Center]

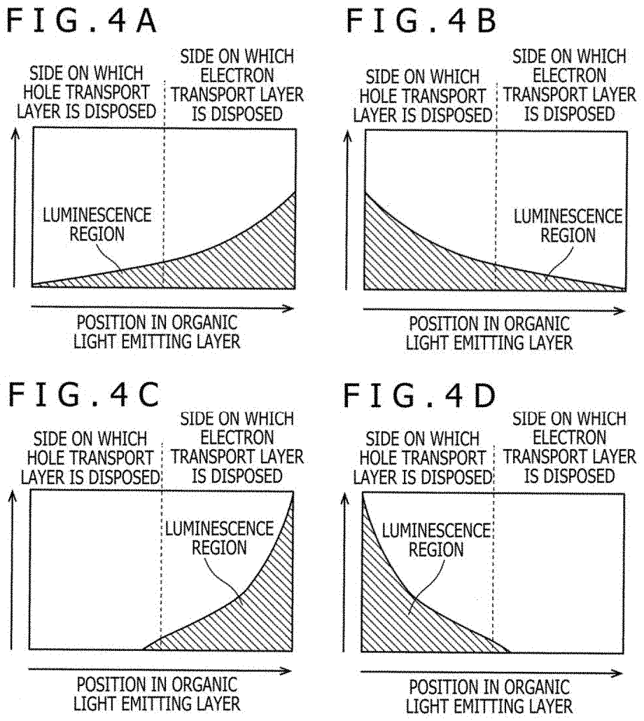

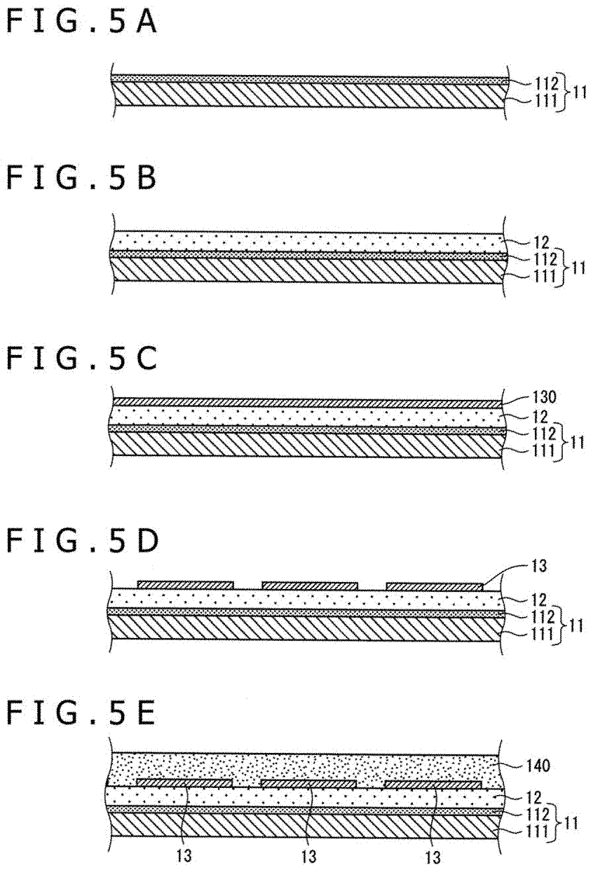

Here, a detailed description will be made about the luminescence center in the light emitting layer. The luminescence center refers to a representative position of a luminescence region to be described below and specifically refers to the position as the center of the region or the position at which the peak of luminescence is obtained. The luminescence region refers to the distribution of excitons generated in the light emitting layer in the organic light emitting layer. FIGS. 4A to 4D represent one example of the luminescence region in the light emitting layer. In FIGS. 4A to 4D, the light emitting layer is divided at the center and is halved into the region on the side on which the hole transport layer is disposed and the region on the side on which the electron transport layer is disposed. “The luminescence region exists on the electron transport layer side” means that 50% or higher of the luminescence region in the light emitting layer exists in the region on the side on which the electron transport layer is disposed as depicted in FIG. 4A, for example. “The luminescence region exists on the hole transport layer side” means that 50% or higher of the luminescence region in the light emitting layer exists in the region on the side on which the hole transport layer is disposed as depicted in FIG. 4B, for example. “The luminescence region is located in the vicinity of the interface with the electron transport layer” means that 90% or higher of the luminescence region in the light emitting layer exists in the region on the side on which the electron transport layer is disposed as depicted in FIG. 4C, for example. “The luminescence region is located in the vicinity of the interface with the hole transport layer” means that 90% or higher of the luminescence region in the light emitting layer exists in the region on the side on which the hole transport layer is disposed as depicted in FIG. 4D, for example. In FIGS. 4A to 4D, one example of the luminescence region is depicted. For example, in some cases, the peak of the luminescence region is located not at the interface of the light emitting layer but in the light emitting layer.

### 4. Conclusion

As described above, in the organic EL element according to the present embodiment, the difference between the LUMO level of the material of the electron injection control layer 18 and the LUMO level of the material of the electron transport layer 19 is equal to or larger than 0.1 eV. Thus, electrons are accumulated on the side of the electron injection control layer 18 in the electron transport layer 19 due to the electron injection barrier Eg(eicl) to the electron injection control layer 18. On the other hand, an electron injection barrier does not exist between the electron injection control layer and the light emitting layer and therefore electrons injected into the electron injection control layer are easily injected into the light emitting layer. Accordingly, the density of electrons that accumulate in the vicinity of the interface between the electron injection control layer 18 and the light emitting layer 17 lowers. Therefore, the deterioration of the luminescent material due to the electrons is inhibited and extension of the lifetime of the organic EL element can be expected.

Furthermore, in the organic EL element according to the present embodiment, the HOMO level of the material of the light emitting layer 17 is higher than the HOMO level of the material of the electron injection control layer 18. Thus, the hole density rises on the side of the electron injection control layer 18 in the light emitting layer 17. Therefore, the density of excitons in the vicinity of the interface with the electron injection control layer 18 in the light emitting layer 17 can be improved. In addition, the performance of electron injection from the electron transport layer 19 to the light emitting layer 17 can be improved, so that the luminous efficiency of the organic EL element can be improved. Accordingly, an effect of improvement in the luminous efficiency based on the TTF can be obtained particularly in a blue luminescent material with low luminous efficiency, or the like.

### 5. Manufacturing Method of Organic EL Element

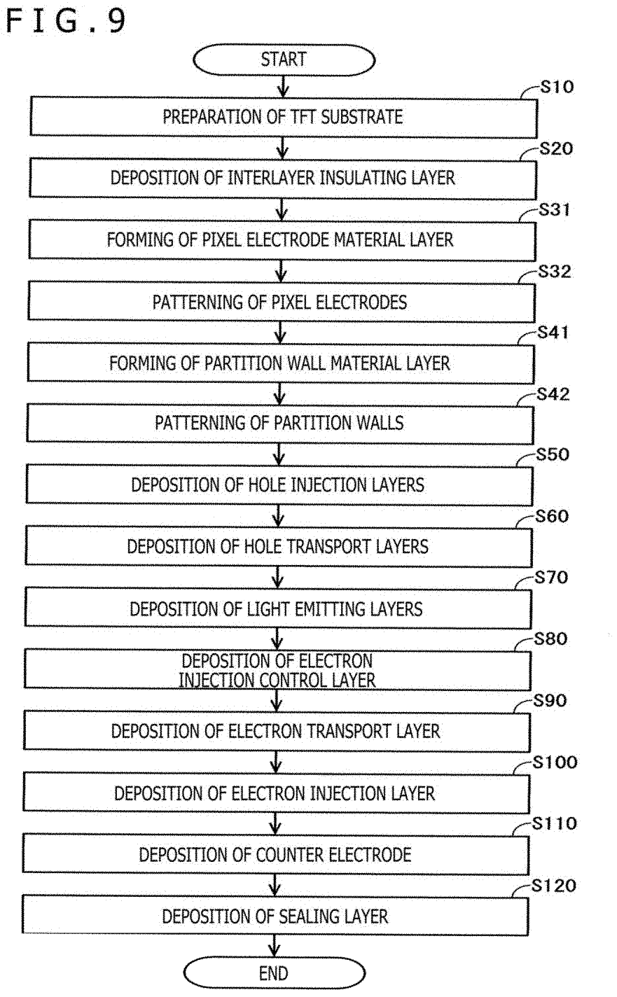

A manufacturing method of the organic EL element will be described by using drawings. FIG. 5A to FIG. 8C are schematic sectional views depicting the state in the respective steps in manufacturing of an organic EL display panel including the organic EL element. FIG. 9 is a flowchart depicting a manufacturing method of the organic EL display panel including the organic EL element.

In the organic EL display panel, a pixel electrode (lower electrode) functions as the anode of the organic EL element and a counter electrode (upper electrode, common electrode) functions as the cathode of the organic EL element.

### (1) Forming of Substrate 11

First, as depicted in FIG. 5A, the TFT layer 112 is deposited on the base 111 to form the substrate 11 (step S10 in FIG. 9). The TFT layer 112 can be deposited by a publicly-known manufacturing method of a TFT.

Next, as depicted in FIG. 5B, the interlayer insulating layer 12 is formed on the substrate 11 (step S20 in FIG. 9). The interlayer insulating layer 12 can be formed to be stacked by using a plasma CVD method, sputtering method, or the like, for example.

Next, a dry etching method is carried out for places over source electrodes of the TFT layer in the interlayer insulating layer 12 and contact holes are formed. The contact holes are formed in such a manner that the surfaces of the source electrodes are exposed at the bottom parts thereof.

Next, a connecting electrode layer is formed along the inner walls of the contact holes. Part of the upper part of the connecting electrode layer is disposed on the interlayer insulating layer 12. For the forming of the connecting electrode layer, a sputtering method can be used, for example, and patterning is carried out by using a photolithography method and a wet etching method after a metal film is deposited.

### (2) Forming of Pixel Electrodes 13

Next, as depicted in FIG. 5C, a pixel electrode material layer 130 is formed on the interlayer insulating layer 12 (S31 in FIG. 9). The pixel electrode material layer 130 can be formed by using a vacuum evaporation method, sputtering method, or the like, for example.

Next, as depicted in FIG. 5D, patterning of the pixel electrode material layer 130 is carried out by etching and plural pixel electrodes 13 marked out for each sub-pixel are formed (step S32 in FIG. 9). This pixel electrode 13 functions as the anode of each organic EL element.

The forming method of the pixel electrodes 13 is not limited to the above-described method. For example, the pixel electrodes 13 and the hole injection layers 15 may be collectively formed by forming a hole injection material layer 150 on the pixel electrode material layer 130 and carrying out patterning of the pixel electrode material layer 130 and the hole injection material layer 150 by etching.

### (3) Forming of Partition Walls 14

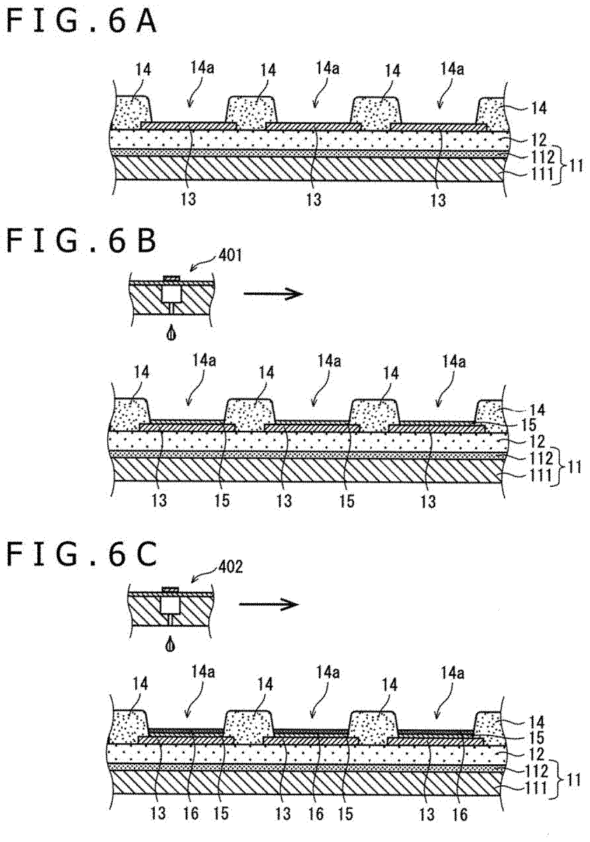

Next, as depicted in FIG. 5E, a resin for partition walls that is the material of partition walls 14 is applied on the pixel electrodes 13 and the interlayer insulating layer 12 to form a partition wall material layer 140. The partition wall material layer 140 is formed by uniformly applying a solution made by dissolving a phenolic resin that is the resin for partition walls in a solvent (for example, mixed solvent of ethyl lactate and GBL) on the pixel electrodes 13 and the interlayer insulating layer 12 by using a spin-coating method or the like (step S41 in FIG. 9). Then, the partition walls 14 are formed by carrying out pattern exposure and development for the partition wall material layer 140 (FIG. 6A, step S42 in FIG. 9) and the partition walls 14 are baked. Thereby, opening parts 14a that become the forming regions of the light emitting layers 17 are defined. The baking of the partition walls 14 is carried out at a temperature of 150° C. to 210° C. inclusive for 60 minutes, for example.

Furthermore, in the forming step of the partition walls 14, moreover surface treatment may be executed for the surfaces of the partition walls 14 by a predetermined alkaline solution, water, organic solvent, or the like or plasma treatment may be executed. This is carried out for the purpose of adjusting the contact angle of the partition wall 14 with respect to ink (solution) applied in the opening parts 14a or for the purpose of giving water-repellency to the surfaces.

### (4) Forming of Hole Injection Layers 15

Next, as depicted in FIG. 6B, ink containing the constituent material of the hole injection layer 15 is discharged from a nozzle of an inkjet head 401 to the opening parts 14a defined by the partition walls 14 and is applied on the pixel electrodes 13 in the opening parts 14a. Then, baking (drying) is carried out to form the hole injection layers 15 (step S50 in FIG. 9).

### (5) Forming of Hole Transport Layers 16

Next, as depicted in FIG. 6C, ink containing the constituent material of the hole transport layer 16 is discharged from a nozzle of an inkjet head 402 to the opening parts 14a defined by the partition walls 14 and is applied on the hole injection layers 15 in the opening parts 14a. Then, baking (drying) is carried out to form the hole transport layers 16 (step S60 in FIG. 9).

### (6) Forming of Light Emitting Layers 17

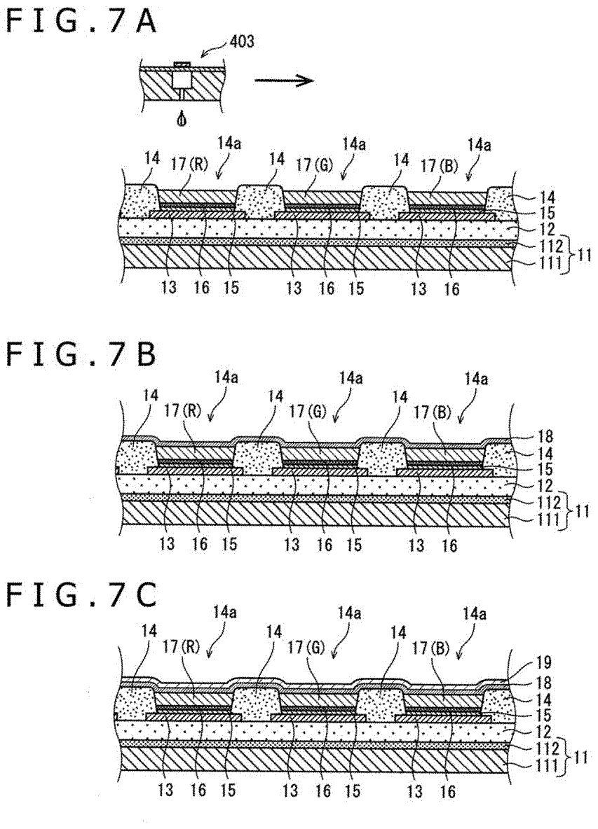

Next, as depicted in FIG. 7A, ink containing the constituent material of the light emitting layer 17 is discharged from a nozzle of an inkjet head 403 and is applied on the hole transport layers 16 in the opening parts 14a. Then, baking (drying) is carried out to form the light emitting layers 17 (step S70 in FIG. 9).

### (7) Forming of Electron Injection Control Layer 18

Next, as depicted in FIG. 7B, the electron injection control layer 18 is formed on the light emitting layers 17 and the partition walls 14 (step S80 in FIG. 9). The electron injection control layer 18 is formed by depositing a low-molecular organic compound as the material of the electron injection control layer 18 in common to each sub-pixel by an evaporation method, for example.

### (8) Forming of Electron Transport Layer 19

Next, as depicted in FIG. 7C, the electron transport layer 19 is formed on the electron injection control layer 18 (step S90 in FIG. 9). The electron transport layer 19 is formed by depositing an organic material with electron transport capability in common to each sub-pixel by an evaporation method, for example.

### (9) Forming of Electron Injection Layer 20

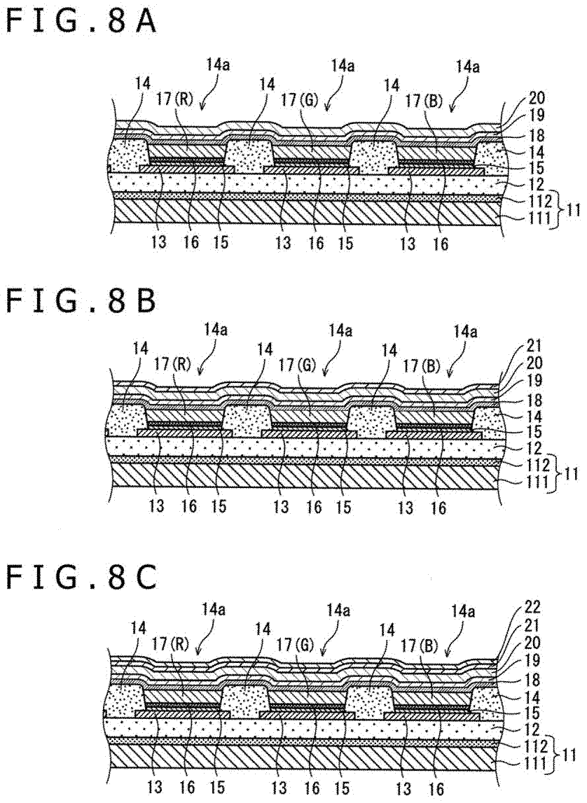

Next, as depicted in FIG. 8A, the electron injection layer 20 is formed on the electron transport layer 19 (step S100 in FIG. 9). The electron injection layer 20 is formed by depositing an organic material with electron transport capability and a doping metal or a compound thereof in common to each sub-pixel by a co-evaporation method, for example.

### (10) Forming of Counter Electrode 21

Next, as depicted in FIG. 8B, the counter electrode 21 is formed on the electron injection layer 20 (step S110 in FIG. 9). The counter electrode 21 is formed by depositing ITO, IZO, silver, aluminum, or the like by a sputtering method or vacuum evaporation method. The counter electrode 21 functions as the cathode of each organic EL element.

### (11) Forming of Sealing Layer 22

At last, as depicted in FIG. 8C, the sealing layer 22 is formed on the counter electrode 21 (step S120 in FIG. 9). The sealing layer 22 can be formed by depositing SiON, SiN, or the like by a sputtering method, CVD method, or the like. A sealing resin layer may be further formed on the inorganic film of SiON, SiN, or the like by applying, baking, and so forth.

A color filter and an upper surface may be placed on the sealing layer 22 and be joined.

### 6. Overall Configuration of Organic EL Display Device

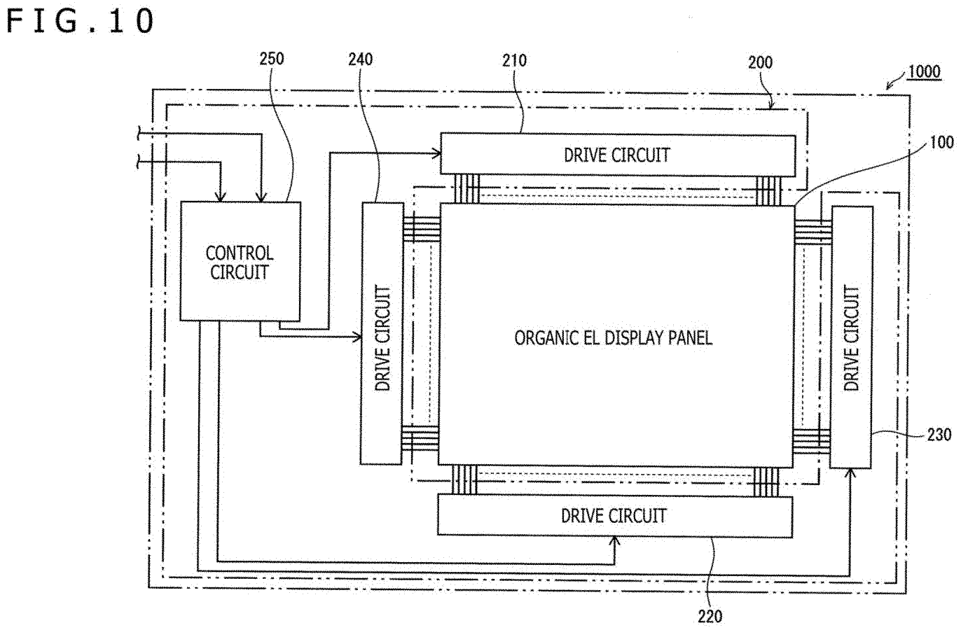

FIG. 10 is a schematic block diagram depicting the configuration of an organic EL display device 1000 including the organic EL display panel 100. As depicted in FIG. 10, the organic EL display device 1000 has a configuration including the organic EL display panel 100 and a drive control unit 200 connected thereto. The drive control unit 200 is composed of four drive circuits 210 to 240 and a control circuit 250.

In the actual organic EL display device 1000, the arrangement of the drive control unit 200 with respect to the organic EL display panel 100 is not limited thereto.

### 7. Modification Examples

(1) In the above-described embodiment, it is assumed that the light emitting layer 17 is composed of a single organic luminescent material. However, the configuration is not limited thereto. For example, the light emitting layer 17 may contain a fluorescent material and a host material, that is, may be composed of plural materials. In this case, it is preferable for the band diagram to satisfy the following condition.

In the relationship between the light emitting layer 17 and the electron injection control layer 18, when electrons are injected from the electron injection control layer 18 into the light emitting layer 17, the electrons are injected into the main material configuring the light emitting layer 17. Therefore, it is preferable to satisfy expression (3) or expression (4) between the material of the electron injection control layer 18 and the main material configuring the light emitting layer 17. Furthermore, when holes flow out from the light emitting layer 17 to the electron injection control layer 18, the holes flow out from the main material configuring the light emitting layer 17 to the electron injection control layer 18. Therefore, it is preferable to satisfy expression (5) or expression (6) between the material of the electron injection control layer 18 and the main material configuring the light emitting layer 17.

Moreover, the following configuration is preferable regarding the electron transport performance and the hole transport performance. Specifically, it is preferable that the hole mobility of the material responsible for hole transport in the light emitting layer 17 be higher than the electron mobility of the material responsible for electron transport in the light emitting layer 17. The material responsible for electron transport and the material responsible for hole transport may be the same or may be different materials.

(2) In the above-described embodiment, it is assumed that the cathode is the counter electrode and the organic EL display device is a top-emission type. However, for example, the anode may be the counter electrode and the cathode may be the pixel electrode. Furthermore, for example, an organic EL display device of a bottom-emission type may be employed.

(3) In the above-described embodiment, the hole injection layer 15 and the hole transport layer 16 are deemed as essential configurations. However, the configuration is not limited thereto. For example, an organic EL element that does not have the hole transport layer 16 may be employed. Furthermore, for example, the organic EL element may have a hole injection-transport layer as a single layer instead of the hole injection layer 15 and the hole transport layer 16.

Moreover, in the above-described embodiment, the electron injection layer 20 is disposed separately from the electron transport layer 19. However, the electron transport layer 19 may double as the electron injection layer.

(4) In the above-described embodiment, the film thickness is depicted regarding each of the light emitting layer and the electron injection control layer. However, this is exemplification as one mode of the embodiment and design may be carried out as appropriate based on optical constants such as the luminescence wavelength, the refractive index, and the light transmittance, electrical characteristics, design of an optical resonator structure, and so forth.

(5) In the embodiment, the configuration in which injection of electrons into the light emitting layer is controlled by using the electron injection control layer is described. However, an embodiment is also conceivable in which a hole injection control layer is disposed between the light emitting layer and the hole transport layer and thereby excitons are concentrated in the vicinity of the interface with the hole injection control layer in the light emitting layer. However, in the case of forming the hole injection layer, the hole transport layer, and the light emitting layer by a coating system, the solvent needs to be selected in such a manner that the ink for forming the functional layer does not dissolve the functional layer that exists directly beneath (functional layer in contact on the anode side). Specifically, in the case of disposing the hole injection control layer, the hole transport layer needs to insoluble in the ink for forming the hole injection control layer and the hole injection control layer needs to be insoluble in the ink for forming the light emitting layer. That is, in the case of forming the hole injection layer, the hole transport layer, and the light emitting layer by a coating system, the combinations of the materials of the hole injection layer, the hole transport layer, the hole injection control layer, and the light emitting layer and the solvents for forming ink needs to be considered in addition to the band structure. Therefore, the range of selection of the material is narrowed. On the other hand, the electron injection control layer is formed by an evaporation method or the like as described above. Therefore, the electron injection control layer offers a wider range of selection of the material compared with the hole injection control layer and is suitable for the organic EL element for which the hole injection layer, the hole transport layer, and the light emitting layer are formed by a coating system.

One embodiment of the present disclosure is the organic electroluminescence element including the pixel electrode (anode), the hole injection layer formed of a coating film, the hole transport layer formed of a coating film, the light emitting layer formed of a coating film, the electron injection control layer formed of an evaporated film, the electron transport layer formed of an evaporated film, the electron injection layer formed of an evaporated film, and the counter electrode (cathode) sequentially. Due to employment of such a configuration, it suffices that the solvent of ink for forming the functional layer be considered only regarding the ink of each of the hole injection layer, the hole transport layer, and the light emitting layer formed by a coating system conventionally, and publicly-known materials can be used as they are. Meanwhile, regarding the material selection of the electron injection control layer, the solvent itself is not used and therefore the solvent does not need to be considered, which provides a wide range of selection of the material.

The organic light emitting panel and the display device according to the present disclosure are described above based on the embodiment and the modification examples. However, techniques of the present disclosure are not limited to the above-described embodiment and modification examples. Modes obtained by making various modifications conceivable by those skilled in the art on the above-described embodiment and modification examples and modes implemented by arbitrarily combining constituent elements and functions in the embodiment and the modification examples without departing from the gist of techniques of the present disclosure are also included in techniques of the present disclosure.

Techniques of the present disclosure are useful for manufacturing an organic EL element with a long lifetime, an organic EL display panel including it, and a display device.

What is claimed is:

1. An organic electroluminescent element obtained by stacking an anode, a light emitting layer, an electron transport layer, and a cathode in that order, the organic electroluminescent element comprising:
an electron injection control layer in contact with both the light emitting layer and the electron transport layer, wherein
the light emitting layer contains a fluorescent material as a luminescent material,
a lowest unoccupied molecular orbital level of a functional material contained in the electron injection control layer is higher than a lowest unoccupied molecular orbital level of a functional material contained in the electron transport layer by 0.1 eV or higher, and
the lowest unoccupied molecular orbital level of the functional material contained in the electron injection control layer is equal to or higher than a lowest unoccupied molecular orbital level of a functional material contained in the light emitting layer.

2. The organic electroluminescent element according to claim 1, wherein
the lowest unoccupied molecular orbital level of the functional material contained in the electron injection control layer is higher than the lowest unoccupied molecular orbital level of the functional material contained in the light emitting layer by 0.1 eV or higher.

3. The organic electroluminescent element according to claim 1, wherein
a highest occupied molecular orbital level of the functional material contained in the electron injection control layer is lower than a highest occupied molecular orbital level of the functional material contained in the light emitting layer.

4. The organic electroluminescent element according to claim 1, wherein
hole mobility of the light emitting layer is higher than electron mobility of the light emitting layer.

5. The organic electroluminescent element according to claim 4, wherein
a distance between a luminescence center of the light emitting layer and a surface of the light emitting layer on a side of the cathode is shorter than a distance between the luminescence center of the light emitting layer and a surface of the light emitting layer on a side of the anode.

6. The organic electroluminescent element according to claim 1, wherein
energy of a singlet exciton in the functional material contained in the electron injection control layer is higher than energy of a singlet exciton in the functional material contained in the light emitting layer.

7. The organic electroluminescent element according to claim 1, wherein
energy of a triplet exciton in the functional material contained in the electron injection control layer is higher than energy of a triplet exciton in the functional material contained in the light emitting layer.

8. An organic electroluminescent display panel comprising:
a plurality of organic electroluminescent elements obtained by stacking an anode, a light emitting layer, an electron transport layer, and a cathode in that order, the organic electroluminescent element including
an electron injection control layer in contact with both the light emitting layer and the electron transport layer, wherein
the light emitting layer contains a fluorescent material as a luminescent material,
a lowest unoccupied molecular orbital level of a functional material contained in the electron injection control layer is higher than a lowest unoccupied molecular orbital level of a functional material contained in the electron transport layer by 0.1 eV or higher, and
the lowest unoccupied molecular orbital level of the functional material contained in the electron injection control layer is equal to or higher than a lowest unoccupied molecular orbital level of a functional material contained in the light emitting layer, over a substrate.

9. A manufacturing method of an organic electroluminescent element, comprising:
preparing a substrate;
forming a pixel electrode over the substrate;
forming a light emitting layer containing a fluorescent material as a luminescent material over the pixel electrode;
forming an electron injection control layer on the light emitting layer;
forming an electron transport layer on the electron injection control layer; and
forming a cathode over the electron transport layer, wherein
a lowest unoccupied molecular orbital level of a functional material contained in the electron injection control layer is higher than a lowest unoccupied molecular orbital level of a functional material contained in the electron transport layer by 0.1 eV or higher, and
the lowest unoccupied molecular orbital level of the functional material contained in the electron injection control layer is equal to or higher than a lowest unoccupied molecular orbital level of a functional material contained in the light emitting layer.
